(19) United States
(12) Patent Application Publication
(10) Pub. No.: US 2018/0083441 A1
(43) Pub. Date: Mar. 22, 2018

(54) METHOD, APPARATUS, AND SYSTEM FOR A SEMICONDUCTOR DEVICE HAVING NOVEL ELECTROSTATIC DISCHARGE (ESD) PROTECTION SCHEME AND CIRCUIT

(71) Applicant: GLOBALFOUNDRIES INC., Grand Cayman (KY)

(72) Inventors: Mahadeva Iyer Natarajan, Clifton Park, NY (US); Chien-Hsin Lee, Malta, NY (US); Manjunatha Prabhu, Malta, NY (US)

(73) Assignee: GLOBALFOUNDRIES INC., GRAND CAYMAN (KY)

(21) Appl. No.: 15/271,058

(22) Filed: Sep. 20, 2016

(51) Int. Cl. H02H 9/04; H02H 1/00; H01L 27/02

(52) U.S. Cl. CPC H02H 9/046; H01L 27/0266; H01L 27/0288; H02H 1/0061

(57) ABSTRACT

Methods, apparatus, and systems relating to a semiconductor device having an ESD function for providing a first ESD current flow in a first path and a second ESD current flow in a second path. The semiconductor device includes a pad for at least one of receiving or transmitting an electrical signal; a victim circuit; an electrostatic discharge (ESD) protection device configured for receiving at least a portion of an ESD current resulting from an ESD event and for protecting the victim circuit from damage from the ESD current; an ESD current control module capable of receiving an ESD current resulting from the ESD event from the pad, wherein the ESD current control module is capable of directing a first ESD current portion through the ESD protection device and a second ESD current portion through the victim circuit. The semiconductor device also comprises a dissipation path for receiving the first and second ESD current portions and directing the first and second ESD current portions through the dissipation path to a ground node.

### BACKGROUND OF THE INVENTION

### Field of the Invention

Generally, the present disclosure relates to the manufacture of sophisticated semiconductor devices, and, more specifically, to various methods, structures, and systems relating to a circuit comprising a novel electrostatic discharge (ESD) protection scheme.

### Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

Integrated circuits including metal-oxide-semiconductor field-effect transistors (MOSFETs) receive input signals and transfer output signals in the form of a voltage. These devices are typically made with very small device dimensions in order to maximize the amount of circuitry that can be implemented on the integrated circuit and to allow the circuitry to operate at high frequencies yet with minimal power demands. A problem with these devices, however, is sensitivity to damage from electrical overstresses applied to the input terminals, output terminals, or to internal circuit nodes of the integrated circuit. For example, the gate oxides for these devices are typically very thin and can break down if an applied voltage exceeds even relatively low levels. Such breakdown may cause immediate or expedited destruction of transistors or other devices. Excess voltage is often caused by stress in the form of electrostatic discharge (ESD). In order to combat problems associated with ESD events, it is known to provide protection devices that provide paths through which to rapidly discharge nodes. However, as described herein, there are various problems associated with state-of-the-art ESD protection schemes.

Generally, in state-of-the-art ESD protection schemes, predetermined paths for ESD currents in conjunction with ESD devices are provided. Further, disallowed paths for ESD currents are also predetermined. FIG. 1 illustrates an example of one such typical ESD protection scheme for protecting a semiconductor device. A generalized block diagram depiction of a typical ESD protection circuit 100 is shown in FIG. 1. A pad 110 may experience an ESD event, causing an ESD current (i_{ESD}) to flow from the pad 110. The ESD device 120 directs all of the ESD current, i_{ESD} through a known ESD path 140.

The ESD device 120 operates to disallow the ESD current, i_{ESD} through a protected or “victim” circuit 130. The victim circuit 130 may be a single device or a plurality of devices of a circuit. The path between the ESD device 120 and the victim circuit 130 is a disallowed path 150 with regard to the ESD current, i_{ESD}. The ESD current, i_{ESD} is directed for dissipation, via a ground path.

FIG. 2 illustrates a more detailed block diagram depiction of a state-of-the-art ESD protection scheme. A semiconductor device 200 comprises an ESD protection scheme that includes plurality of ESD devices. The device 200 includes a plurality of input/output pads, e.g., pad P1 (205) and pad P2 (207). The device 200 may comprise a digital circuitry 240, which represents a plurality of digital components and circuits. The device 200 may also comprise an analog circuitry 250, which represents a plurality of analog components and circuits. A plurality of diodes (D1-215, D2-217, D3-218, and D4-219) are positioned in the circuit 200 in order to direct ESD currents in predetermined desired paths.

The device 200 also comprises a 1^{st} ESD device 270 and a 2^{nd} ESD device 280. The ESD devices 270, 280 are capable of dissipating a predetermined amount of ESD current and directing the ESD current through predetermined desired paths. A 1^{st} ESD power clamp 260a and a 2^{nd} ESD power clamp 260b operate in conjunction with the ESD devices 270, 280 to clamp the maximum power to a predetermined level and to direct the ESD current paths. The ESD power clamps (260a, 260b), the ESD devices (270, 280), and the diodes D1-D4 operate together to direct ESD currents through predetermined desired paths and prevent the ESD currents through undesired paths.

If an ESD event causes an ESD current to flow through circuit, the device 200 is configured to direct the ESD current through predetermined desired path (denoted by the solid arrows) 220a, 220b, 220c, 220d. Further, the device is also configured to prevent the ESD current through predetermined undesired path (denoted by the shaded arrows) 230a, 230b, 230c, 240d. The undesired path for the ESD current refers to currents paths that could cause damage the victim devices (i.e., the digital circuitry 240 and the analog circuitry 250) if the ESD current were to flow through them.

As an example, if an ESD event causes a ESD current to flow through the pad P1 205, the diode D1 215 turns on and allows the ESD current to flow the from the pad P1 205, through the 1^{st} ESD power clamp 260a, and through the 1^{st} ESD device 270, as indicated by the arrows 220a and 220b. A portion of the ESD current also travels through the 1^{st} ESD power clamp 260a and the 2^{nd} ESD power clamp 260b, and indicated by the arrows 220c and 220e. The ESD current, traveling through desired paths (260a-d) and through the digital and analog ground nodes, is dissipated through the pad P2 207, into ground.

Among the problems associated with the state-of-the-art ESD scheme include the fact that a large number of ESD devices are required to adequately protect various victim circuits. Further, large-sized ESD devices are required to dissipate all of the ESD current and to prevent the ESD current on disallowed paths. This requires large amounts of resources, such as circuit components, as well as ever-shrinking silicon real estate. The resource demands of state-of-the-art ESD protection schemes may cause problems in reducing device dimensions and power consumption.

It would therefore be desirable to have protection devices which protect semiconductor from ESD, especially at higher ESD currents, while not significantly increasing the size of ESD protection circuits.

The present disclosure may address and/or at least reduce one or more of the problems identified above regarding the prior art and/or provide one or more of the desirable features listed above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus, and systems relating to a semiconductor device having an ESD function for providing a first ESD current flow in a first path and a second ESD current flow in a second path. The semiconductor device includes a pad for at least one of receiving or transmitting an electrical signal; a victim circuit; an electrostatic discharge (ESD) protection device configured for receiving at least a portion of an ESD current resulting from an ESD event and for protecting the victim circuit from damage from the ESD current; an ESD current control module capable of receiving an ESD current resulting from the ESD event from the pad, wherein the ESD current control module is capable of directing a first ESD current portion through the ESD protection device and a second ESD current portion through the victim circuit. The semiconductor device also comprises a dissipation path for receiving the first and second ESD current portions and directing the first and second ESD current portions through the dissipation path to a ground node.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates an example of one such typical ESD protection scheme for protecting a semiconductor device;

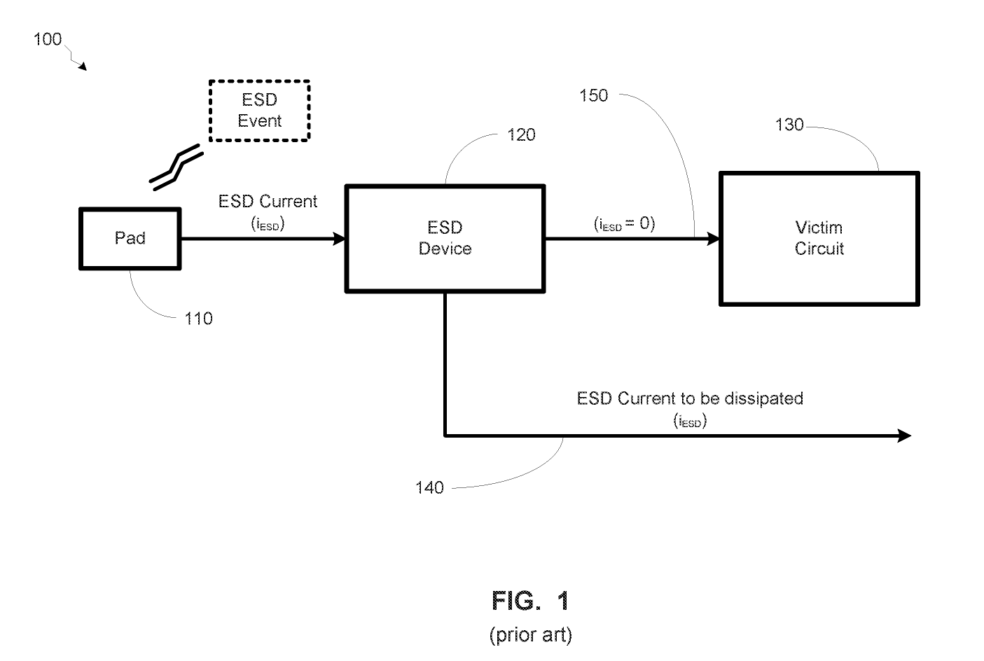

FIG. 2 illustrates a more detailed block diagram depiction of a state-of-the-art ESD protection scheme;

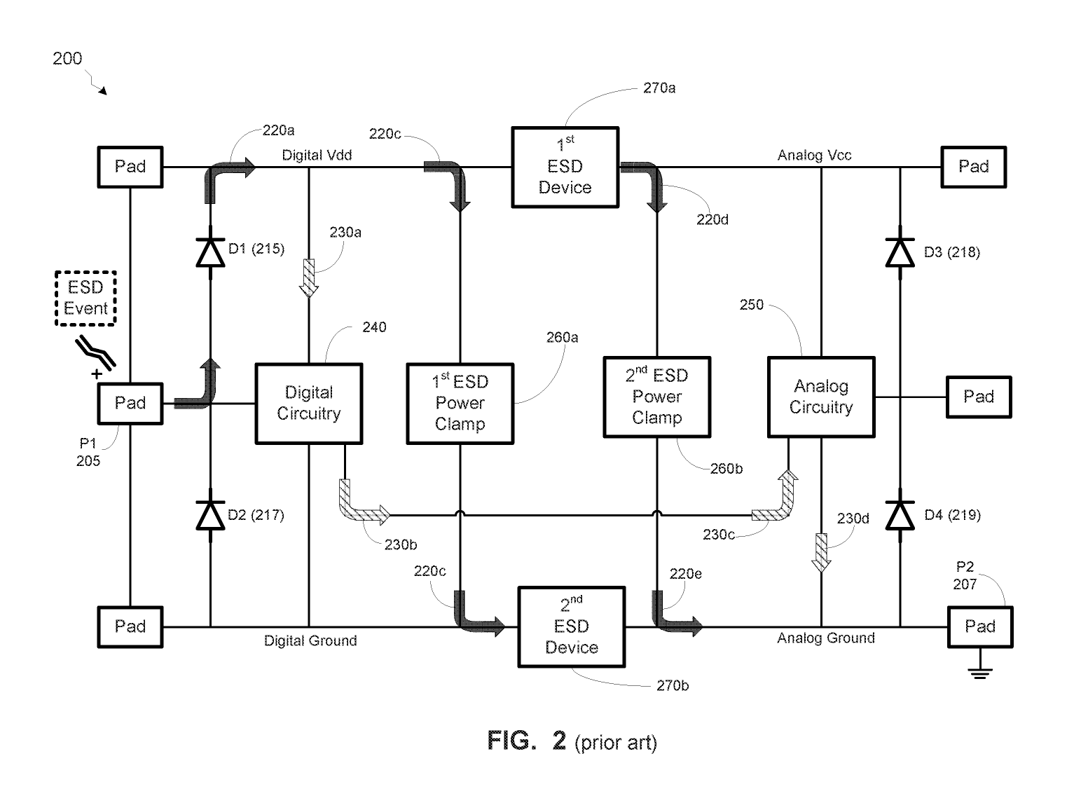

FIG. 3 illustrates a stylized block diagram depiction of an ESD protection scheme, in accordance with some embodiments;

FIG. 4 illustrates a more detailed stylized block diagram depiction of an ESD protection scheme, in accordance with at least one embodiment herein;

FIG. 5 illustrates more detailed stylized block diagram of an ESD protection scheme in accordance with embodiments herein;

FIG. 6 illustrates a stylized circuit representation of ESD protection scheme in accordance with embodiments herein; and

FIG. 7 illustrates a stylized depiction of a system for fabricating a semiconductor device 100, in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for dissipating ESD currents caused by an ESD event. Embodiments herein provide for dissipating a portion of an ESD current through a predetermined, desired or primary ESD path, and another portion of the ESD current through a predetermined secondary ESD path. The primary ESD path may comprise ESD protection devices, wherein the secondary path may comprise circuitry that is to be protected from ESD events, i.e., the so-called “victim” devices. The current path(s) for the ESD current may be configured to only be active during and ESD event.

In this manner, smaller ESD protection devices may be used, while providing greater ESD protection by dissipating some portions of the ESD current through paths that comprise victim devices. However, the portions of the ESD current that are sent through paths that comprise victim devices are limited to current values that are not capable of damaging the victim devices. In this manner, the dedicated ESD protection devices may be of smaller scale, while the overall system is capable of handling ESD currents that are larger in magnitude than what would be acceptable if the entirety of the ESD current were sent through the dedicated ESD path. Accordingly, one or more secondary paths for guiding portions of an ESD current may be provided through the victim devices (e.g., analog circuitry, digital circuitry, firmware circuitry, etc.) such that the dedicated ESD devices and dedicated ESD current paths would not absorb the entire magnitude of the ESD current. Therefore, embodiments herein provide for a desired ESD current path as well as a novel extra-desired ESD current path that could work in conjunction (with the desired ESD current path) to dissipate the entirety of the ESD current while allowing for a smaller ESD device/path footprint in a semiconductor device.

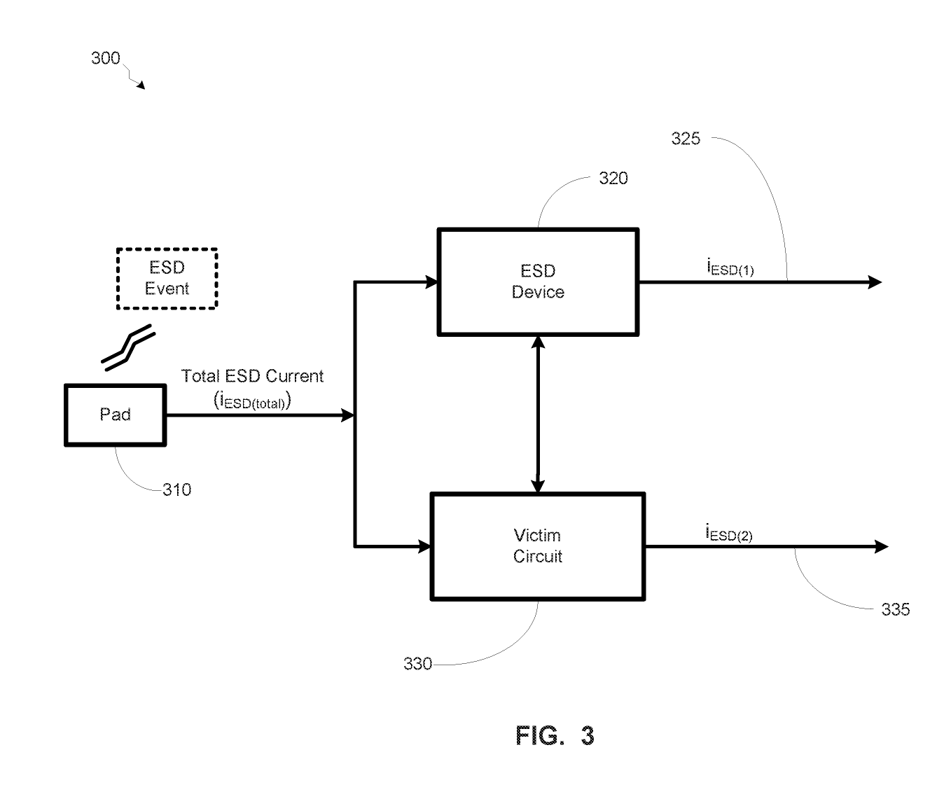

FIG. 3 illustrates a stylized block diagram depiction of an ESD protection scheme, in accordance with some embodiments herein. A pad 310 of a semiconductor device 300 may experience an ESD event, causing an ESD current (i_{ESD}) to flow from the pad 310. The device 300 comprises an ESD protection device 320 that is provided to protect a victim circuitry 330 from an ESD event. The ESD protection device 320 may comprise one or more of a conductive material, dissipative material, shielding material, and or anti-static material. The ESD device 320 may represent a plurality of devices (i.e., ESD current dissipating device, ESD power clamp device, etc.) that are capable of dissipating energy from an ESD event. The victim circuitry 330 may represent one or more circuits (e.g., digital circuitry, analog circuitry, and/or firmware circuitry) that are to be protected from an ESD event.

The ESD device 320 is configured to dissipate a first portion of the ESD current (i_{ESD(1)}) through a first predetermined ESD path 325 (i.e., a primary ESD current path). Further, a second portion of the ESD current (i_{ESD(2)}) is directed through the victim circuitry 330, which is a second predetermined ESD path 335 (i.e., a secondary ESD current path). The magnitude of i_{ESD(2)} is designed to have a maximum value such that components of the victim circuitry 330 would not be damaged, wherein i_{ESD(max)} is the maximum allowable ESD current that would not damage a component in the victim circuitry (see Equation 1).

i_{ESD(2)}<i_{ESD(max)} Equation 1

In one embodiment, the ESD device 320 operates to limit the second ESD current, i_{ESD(2)} to this maximum value (i_{ESD(max)}). The sum of the first ESD current, i_{ESD(1)} and the second ESD current, i_{ESD(2)} equals to the total ESD current (i_{ESD(total)}), as shown in Equation 2.

i_{ESD(total)}=i_{ESD(1)}+i_{ESD(2)} Equation 2

Therefore, the ESD device 320 is configured to handle a first ESD current i_{ESD(1)} that is at least of a value that is the difference between the total ESD current and the maximum allowable ESD current that would not damage a component in the victim circuitry, i.e., i_{ESD(max)} (see Equation 3). In this manner, designers can design the size/configuration of ESD devices based on the value of the first ESD current, i_{ESD(1)}.

i_{ESD(1)}≧i_{ESD(total)}−i_{ESD(max)} Equation 3

The total ESD current, i_{ESD(total)} is dissipated, e.g., to a predetermined ground path. Embodiments herein provide for distributing the total ESD current i_{ESD(total)} through a plurality of ESD current paths, a primary ESD path through one or more ESD devices, and a secondary path through one or more victim devices. In one embodiment, the ESD paths are active only during an ESD event. In this manner, the ESD devices may be designed using smaller device footprints, (i.e., sufficient to provide a dissipation ESD current path for the first ESD current, i_{ESD(1)} while still providing sufficient protection for victim devices).

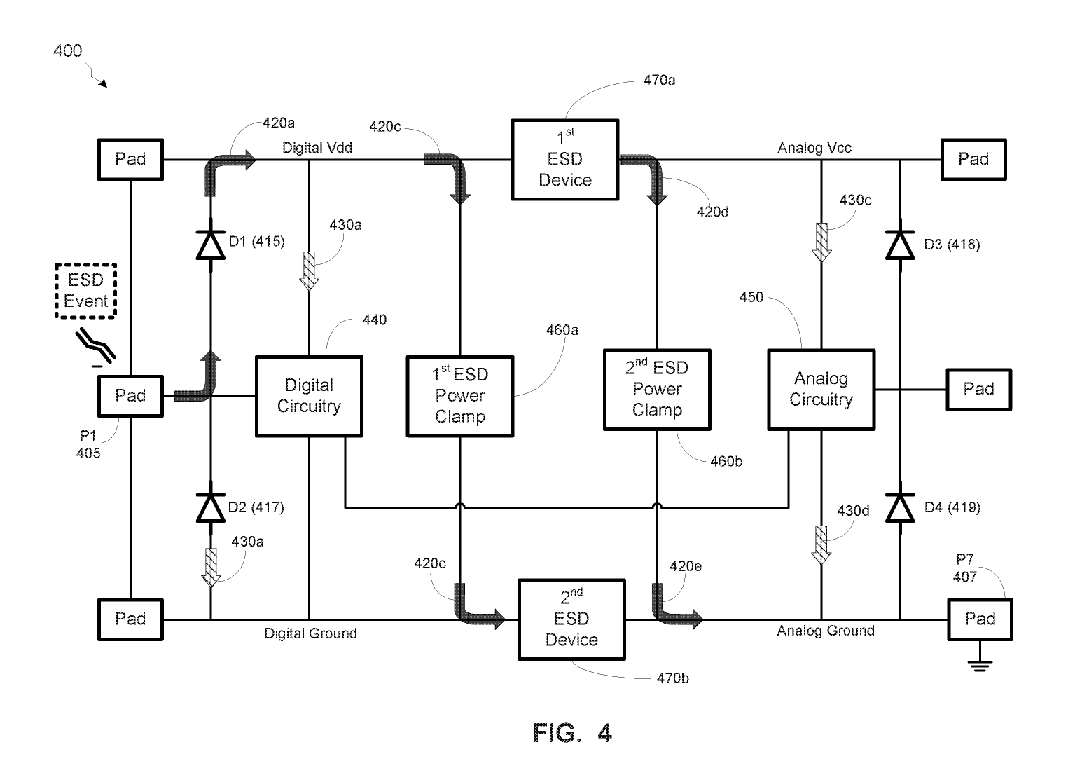

FIG. 4 illustrates a more detailed stylized block diagram depiction of an ESD protection scheme, in accordance with at least one embodiment herein. A semiconductor device 400 may comprise an ESD protection scheme that includes plurality of ESD devices. The device 400 may include a plurality of input/output pads, e.g., pad P1 (405) and pad P2 (407). The device 400 may comprise a digital circuitry 440, which may represent a plurality of digital and/or firmware components and/or circuits. The device 400 may comprise an analog circuitry 450, which may represent a plurality of analog components and/or circuits.

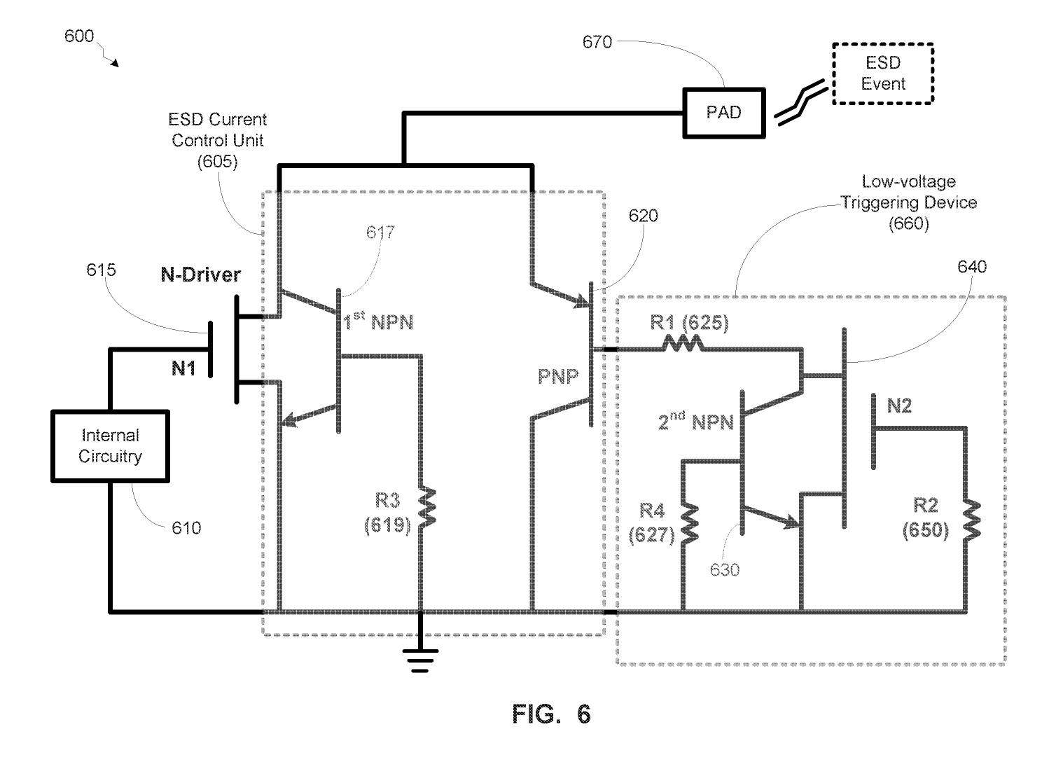

The device 400 comprises a plurality of diodes (D1-415, D2-417, D3-418, and D4-419) that are positioned in the circuit 200 in order to direct a 1^{st} portion of the ESD current, a 2^{nd} portion of the ESD current, through an Nth portion of the ESD current through predetermined paths. For example, the 1^{st} portion of the ESD current may be the largest portion of the ESD current and is directed through ESD components, while the 2^{nd} through Nth portions of the ESD current may be smaller in magnitude and are directed through predetermined path that comprises victim components. However, the 2^{nd} through Nth portions of the ESD current are directed in such a manner that their respective magnitudes are sufficiently small as to not damage victim components in their respective paths. In some embodiments, the one or more of the diodes (D1 415, D2 417, D3 418, and D4 419) may be effectively formed using BJT transistors, as exemplified below in FIG. 6.

Continuing referring to FIG. 4, the device 400 also comprises a 1^{st} ESD protection device 470 and a 2^{nd} ESD protection device 480. The ESD devices 470, 480 are capable of dissipating a predetermined amount of ESD current and directing the ESD current through predetermined desired paths. The 1^{st} and 2^{nd} ESD protection devices 720a-b may comprise one or more of a conductive material, dissipative material, shielding material, and or anti-static material. A 1^{st} ESD power clamp 460a and a 2^{nd} ESD power clamp 460b operate in conjunction with the ESD devices 470, 480 to clamp the maximum power to a predetermined level and to direct the ESD current paths. The ESD power clamps, 460a, 460b, the ESD devices 470, 480, and the diodes D1-D4 work together to direct various portions of the ESD current through predetermined primary and secondary ESD current paths. In some alternative embodiments, the 1^{st} ESD device 470 may be an optional device.

In the event an ESD event causes an ESD current to flow through circuit, the device 400 is configured to direct a 1^{st} portion of the ESD current through predetermined primary ESD paths (denoted by the solid arrows) 420a, 420b, 420c, 420d. Further, the device 400 is also configured to direct a 2^{nd} portion of the ESD current through predetermined secondary paths (denoted by the shaded arrows) 430a, 430b, 430c, 440d. The secondary path for the 2^{nd} portion of the ESD current is limited in magnitude such that they would not cause damage to victim devices (i.e., the digital circuitry 240 and the analog circuitry 250). The primary or 1^{st} portion of the ESD current may be the largest portion of the ESD current and is directed through the various ESD components of the device 400.

As an example, an ESD event may cause a negative charge to accumulate at the pad P1 405. In this case, a secondary ESD current flow from the pad P1 405 towards logic ground may occur. The negative ESD charge may cause the diode D2 417 to turn on, causing a current flow towards logic ground. However, when D2 turns on, a path through D1 may also be created. The diode D1 415 provides a primary ESD current path 420a, which provides a current flow 420e through the 1^{st} ESD device 470a, and a current path 420b through the 1^{st} ESD power claim 460a. The primary ESD current path may then follow the current path 420d onto the pad P2 407, which may be electrically coupled to ground. The primary current path sinks the 1^{st} portion of the ESD current through the pad P2 407 to ground. In some embodiments, D1 415 may be integrated into a victim device.

As a result of the negative ESD charge at the pad P1 405, the diode D2 417 turns on, which provides a secondary path for the ESD current. In some embodiments, a low-voltage triggering PNP bipolar junction transistor (BJT) may be configured to perform the functions of D2 417, while an NPN BJT transistor may perform the function of D1 415. When triggered, the PNP BJT (D2 417) may turn on to sink a portion of the ESD current. As such, the secondary current path may include the current path 430a, which flows through logic ground, the current path 430b, which flows through the digital circuitry 440, and current path 430c, which flows through the analog circuitry 450. The secondary current path may sink the 2^{nd} portion of the ESD current through the pad P2 407 to ground. The secondary current path limits the maximum magnitude of the 2^{nd} portion of the ESD current to a value such that the victim circuits would not be damaged.

The primary ESD current paths (420a-e) carry the bulk of the total ESD current. In this manner, the bulk of the ESD current (i.e., the 1^{st} portion of the ESD current) travels through the ESD devices, while a smaller portion of the ESD current (i.e., the 2^{nd} portion of the ESD current) travels through the victim devices (i.e., the digital circuitry 440 and/or the analog circuitry 450). Accordingly, this allows for smaller ESD devices, while providing sufficient ESD protection. In one embodiment, the ESD current paths are active only during an ESD event and the immediate aftermath.

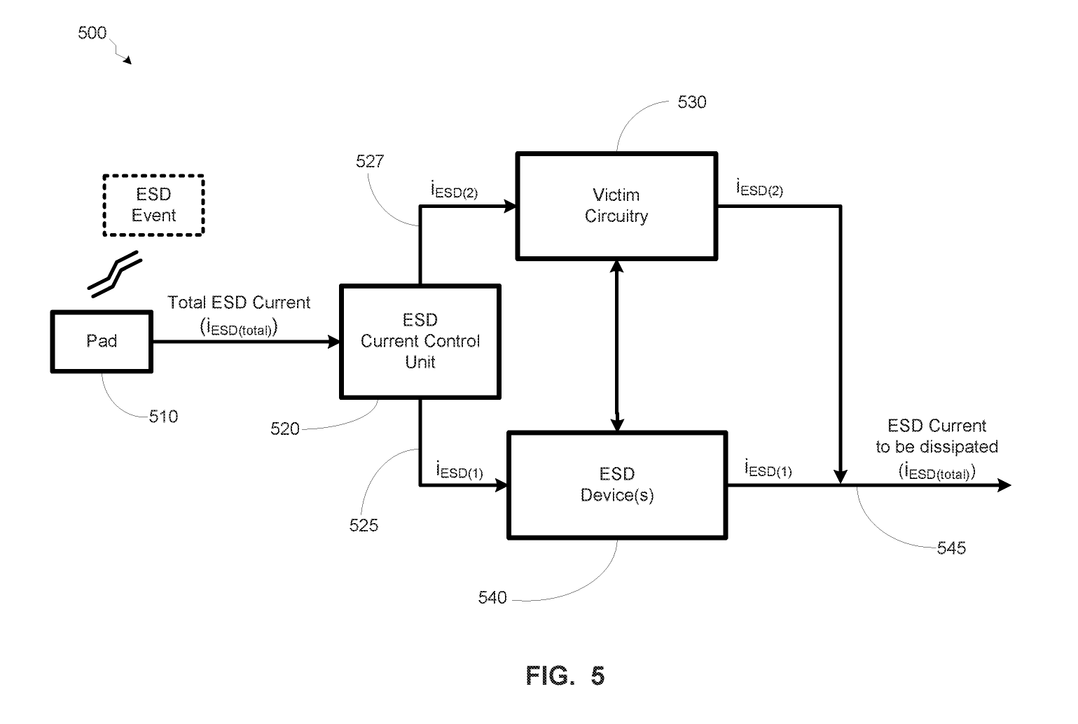

FIG. 5 illustrates more detailed stylized block diagram of an ESD protection scheme in accordance with embodiments herein. A pad 510 of a semiconductor device 500 may experience an ESD event, causing an ESD current (i_{ESD(total)}) to flow from the pad 410 into the device 500. The device 500 comprises an ESD device 540 that is configured to protect a victim device 530 from an ESD event. The ESD device 540 may represent a plurality of devices (i.e., ESD current dissipating device, ESD power clamp device, etc.) that are capable of dissipating energy from an ESD event. The victim circuitry 530 may represent one or more circuits (e.g., digital circuitry, analog circuitry, firmware circuitry) that are to be protected from an ESD event.

The device comprises an ESD current control unit 520 configured to direct a 1^{st} ESD current portion (i_{ESD(1)}) of the total ESD current, i_{ESD(total)} towards the ESD devices 540 and a 2^{nd} ESD current portion (i_{ESD(2)}) of the total ESD current, i_{ESD(total)} towards the victim circuitry 530. The ESD current control unit 520 may be pre-programmed or may be programmed remotely to adjust the amount of current send through the ESD devices 540, as well as the amount of current send through the victim circuitry 530.

The ESD device 520 is configured to dissipate a 1^{st} portion of the ESD current (i_{ESD(1)}), i.e., the primary ESD current path 545. Further, the 2^{nd} portion of the ESD current (i_{ESD(2)}) is directed through the victim circuitry 530, i.e., a secondary ESD path 527. The magnitude of i_{ESD(2)} is designed to have a maximum value such that components of the victim circuitry 330 would not be damaged.

The sum of the magnitude of the first ESD, i_{ESD(1)} current and the second ESD current i_{ESD(2)} equals to the magnitude of the total ESD current (i_{ESD(total)}), which may be sunk into a ground path. That is, the total ESD current, i_{ESD(total)} is dissipated into a predetermined ground path. In one embodiment, the ESD paths are active only during an ESD event. In this manner, the ESD devices may be designed using smaller device footprints, (i.e., sufficient to provide a dissipation ESD current path for the first ESD current, i_{ESD(1)} while still providing sufficient protection for victim devices).

FIG. 6 illustrates a stylized circuit representation of ESD protection scheme in accordance with some embodiments herein. A device 600 may comprise an internal circuitry 610, which may comprise a plurality of analog, digital, and/or firmware circuits. Further, the internal circuitry 610 may include a plurality of ESD devices. The device 600 comprises an N-driver, i.e., N1 615, which in one embodiment may be a MOSFET device. In one example, the N-driver, N1 615 may be an output signal driver that is capable of driving an output signal from the internal circuitry 610. The drain terminal of the N-driver, N1 615 is electrically coupled to a pad 670 of the device 600, while its source terminal is coupled to ground.

The device 600 may also comprise an ESD current control unit 605, operatively coupled to the N-driver, N1 615. In this example, the N-driver, N1 615 is a victim device that is to be protected from an ESD event by the ESD current control unit 605. The ESD control unit 605 is capable of activating an ESD current control scheme during an ESD event.

The ESD current control unit 605 comprises a plurality of BJT transistors, and a MOSFET transistor configured to activate ESD protection during an ESD event and direct a portion of the ESD current through N1 615 (victim device), and another current portion through the ESD protection circuit. The ESD current control unit 605 comprises an NPN BJT transistor 617, whose emitter and collector nodes are respectively coupled to the N1 transistor 615 across its drain and source nodes. The base of the NPN transistor 617 is coupled to ground through a resistor R3 619.

The ESD current control unit 605 also comprises a PNP BJT transistor 620, which is configured in parallel across the N-driver 615. The PNP transistor 620 is configured to be in an off-state during normal operation, and in an on-state during an ESD event. The PNP transistor is implemented such that a low-voltage triggering device 660 can trigger the PNP transistor 620 to turn on during an ESD event.

In one embodiment, the low-voltage triggering device 660 comprises an “N-set” circuit. The base of the PNP transistor 620 is coupled to a resistor R1 (625). The low-voltage triggering device 660 also comprises a NPN BJT transistor 630 operatively coupled to an NFET transistor N2 640.

The resistor R1 625 that is coupled to the PNP transistor 620 is also coupled to the collector node of the NPN transistor 630. The base of the NPN transistor 630 is coupled to a resistor R4 624, which is coupled to ground. The source and drain nodes of N2 640 are coupled in parallel to the source and emitter nodes of the NPN transistor 630. The gate of N2 640 is coupled to a resistor R2 650, which is also coupled to round.

The transistor N2 640 is off during normal operation of the device 600 and turns on during an ESD event on the pad 670. When N2 640 turns on (during an ESD event), the NPN transistor 630 turns on as a result. This creates an ESD current flow path through the NPN transistor 630 for the flow of ESD current.

Further, once the NPN transistor 630 is triggered on by N2 640, a base current is provided to turn on the PNP transistor 620. This also creates a current flow path for the ESD current. Due to the smaller voltage of the low voltage triggering device 660, the majority of the ESD current flows through the PNP transistor 620. Accordingly, during an ESD event, a small portion of the ESD current of an ESD event flows through the victim device (i.e., the N-driver N1 615), whereas a majority of the ESD current flows through the PNP transistor 620, and another portion of the ESD current flows through the NPN transistor 640, all to ground. In this manner, a PNP transistor that is capable of sinking a majority of the ESD current of an ESD event is performed when a low-voltage triggering device 660 comprising an NFET device 640 turns on the PNP transistor 620. Therefore, the device 600 comprises an ESD protection scheme that is active only during an ESD event and sinks a majority of an ESD current through an ESD protection scheme, and a small portion of the ESD current through a victim device. The bulk of the ESD protection scheme of the device if off during normal operations of the device 600.

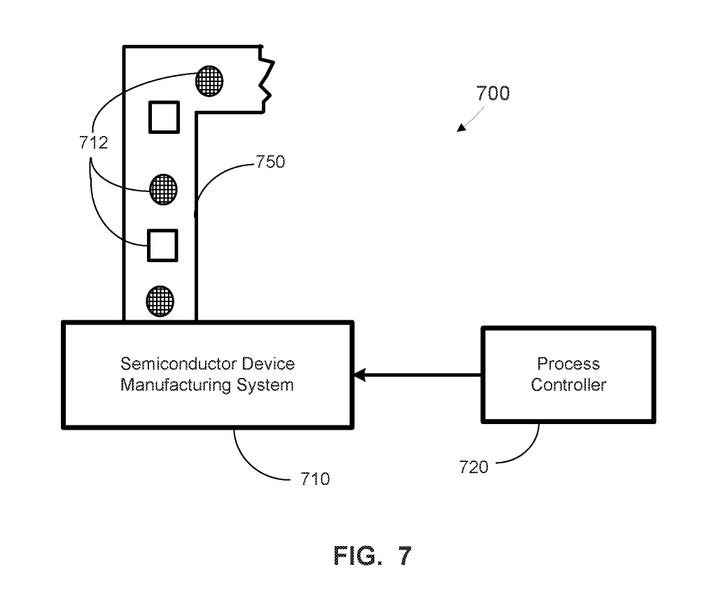

Turning now to FIG. 7, a stylized depiction of a system for fabricating a semiconductor device 100, in accordance with embodiments herein, is illustrated. The system 700 of FIG. 7 may comprise a semiconductor device manufacturing system 710 and a process controller 720. The semiconductor device manufacturing system 710 may manufacture semiconductor devices based upon one or more instruction sets provided by the process controller 720.

In one embodiment, the instruction set may comprise instructions to form a semiconductor device comprising an ESD circuitry for implementing an ESD scheme in accordance with embodiments herein.

The semiconductor device manufacturing system 710 may comprise various processing stations, such as etch process stations, photolithography process stations, CMP process stations, etc. One or more of the processing steps performed by the semiconductor device manufacturing system 710 may be controlled by the process controller 720. The process controller 720 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 710 may produce semiconductor devices 712 (e.g., integrated circuits comprising the devices and ESD protection circuits described above) on a medium, such as silicon wafers. The semiconductor device manufacturing system 710 may provide processed semiconductor devices 712 on a transport mechanism 750, such as a conveyor system. In some embodiments, the conveyor system may be sophisticated clean room transport systems that are capable of transporting semiconductor wafers. In one embodiment, the semiconductor device manufacturing system 710 may comprise a plurality of processing steps, e.g., the 1^{st} process step, the 2^{nd} process step, etc.

In some embodiments, the items labeled “100” may represent individual wafers, and in other embodiments, the items 100 may represent a group of semiconductor wafers, e.g., a “lot” of semiconductor wafers. The semiconductor device 712 may comprise one or more of a transistor, a capacitor, a resistor, a memory cell, digital circuitry, analog circuitry, firmware circuitry, a processor, and/or the like.

The system 700 may be capable of manufacturing various products involving various technologies. For example, the system 700 may produce devices of CMOS technology, Flash technology, BiCMOS technology, power devices, memory devices (e.g., DRAM devices), NAND memory devices, and/or various other semiconductor technologies.

The methods described above may be governed by instructions that are stored in a non-transitory computer readable storage medium and that are executed by, e.g., a processor in a computing device. Each of the operations described herein (e.g., FIG. 7) may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. A method, comprising:
determining whether an electrostatic discharge (ESD) event has occurred in a semiconductor device;
providing a first current path comprising an ESD protection circuit, wherein said first current is configured for directing a first portion of an ESD current resulting from said ESD event in response to determining that an ESD event has occurred; and
providing a second current path comprising at least one of an analog circuit and a digital circuit, wherein said second current path being configured for directing a second portion of said ESD current through, wherein the magnitude of said second portion of the ESD current is below a predetermined level for avoiding damage to said analog and said digital circuit;

2. The method of claim 2, wherein providing said first portion of said ESD current is a majority of said ESD current.

3. The method of claim 2, wherein said first current path is active during said ESD event and is inactive during normal operations of said semiconductor device.

4. The method of claim 1, wherein providing said current path comprises:
providing a plurality of diodes configured to direct said first portion the ESD current to a ground node during an ESD event;
providing at least one ESD power clamp; and
providing at least one ESD protection device.

5. The method of claim 4, wherein providing said second current path comprises providing a current path that limits the amount of ESD current below a current level that could damage said analog circuit or said digital circuit.

6. A semiconductor device, comprising:
a pad for at least one of receiving or transmitting an electrical signal;
a victim circuit;
an electrostatic discharge (ESD) protection device configured for receiving at least a portion of an ESD current resulting from an ESD event and for protecting said victim circuit from damage from said ESD current;
an ESD current control module capable of receiving an ESD current resulting from said ESD event from said pad, wherein said ESD current control module is capable of directing a first ESD current portion through said ESD protection device and a second ESD current portion through said victim circuit; and
a dissipation path for receiving said first and second ESD current portions and directing said first and second ESD current portions through said dissipation path to a ground node.

7. The semiconductor device of claim 6, wherein said victim circuit comprises at least one of an analog circuit, a digital circuit, and a firmware circuit.

8. The semiconductor device of claim 7, wherein said first ESD current portion comprises a majority of said ESD current and said second ESD current portion comprises an amount of ESD current below a current level that could damage said analog circuit or said digital circuit

9. The semiconductor device of claim 6, wherein said ESD current control unit comprises:
a first diode for providing a first current path for said first ESD current portion; and
a second diode for providing a second current path through said victim circuit.

10. The semiconductor device of claim 6, wherein said ESD current control unit comprises:
a first NPN transistor operatively coupled in a parallel format to at least a portion of said victim circuit, said NPN transistor to turn on for conducting a portion of said ESD current during said ESD event;
a PNP transistor configured substantially in parallel to said first NPN transistor, said PNP transistor configured to turn on for conducting a portion of said ESD current during said ESD event; and
a low voltage triggering device configured to turn on said PNP transistor during said ESD event.

11. The semiconductor device of claim 10, wherein the base of said first NPN transistor is coupled to a first resistor, wherein said first resistor is coupled to a ground node.

12. The semiconductor device of claim 10, wherein low voltage triggering device comprises:
a second resistor coupled to the base of said PNP transistor;
a second NPN transistor, wherein the collector of said NPN transistor is coupled to said second resistor, and the base of said NPN transistor is coupled to ground through a third resistor; and
a field effect transistor (FET) coupled in parallel to said second NPN transistor, wherein said gate of said FET is coupled to ground through a fourth resistor.

13. The semiconductor device of claim 12, wherein said first ESD current portion flow through said first NPN transistor and said second ESD current portion flows through said PNP transistor.

14. The semiconductor device of claim 12, wherein said low voltage triggering device is in an off state during normal operation of said semiconductor device and wherein said low voltage triggering device is in an active state during said ESD event.

15. A system, comprising:
a process controller, configured to provide an instruction set for manufacture of a semiconductor device to a manufacturing system; and
the manufacturing system, configured to manufacture the semiconductor device according to the instruction set;
wherein the instruction set comprises instructions to form a semiconductor device comprising:
a pad for at least one of receiving or transmitting an electrical signal;
a victim circuit;
an electrostatic discharge (ESD) protection device configured for receiving at least a portion of an ESD current resulting from an ESD event and for protecting said victim circuit from damage from said ESD current;
an ESD current control module capable of receiving an ESD current resulting from said ESD event from said pad, wherein said ESD current control module is capable of directing a first ESD current portion through said ESD protection device and a second ESD current portion through said victim circuit; and
a dissipation path for receiving said first and second ESD current portions and directing said first and second ESD current portions through said dissipation path to a ground node.

16. The system of claim 15, wherein said first ESD current portion comprises a majority of said ESD current and said second ESD current portion comprises an amount of ESD current below a current level that could damage said analog circuit or said digital circuit

17. The system of 15, wherein said ESD current control unit comprises:
a first diode for providing a first current path for said first ESD current portion;
a second diode for providing a second current path through said victim circuit;
a first NPN transistor operatively coupled in a parallel format to at least a portion of said victim circuit, said NPN transistor to turn on for conducting a portion of said ESD current during said ESD event;
a PNP transistor configured substantially in parallel to said first NPN transistor, said PNP transistor configured to turn on for conducting a portion of said ESD current during said ESD event; and
a low voltage triggering device configured to turn on said PNP transistor during said ESD event.

18. The system of claim 17, wherein the base of said first NPN transistor is coupled to a first resistor, wherein said first resistor is coupled to a ground node.

19. The system of claim 17, wherein low voltage triggering device comprises:
a second resistor coupled to the base of said PNP transistor;
a second NPN transistor, wherein the collector of said NPN transistor is coupled to said second resistor, and the base of said NPN transistor is coupled to ground through a third resistor; and
a field effect transistor (FET) coupled in parallel to said second NPN transistor, wherein said gate of said FET is coupled to ground through a fourth resistor.

20. The system of claim 19, wherein said first ESD current portion flow through said first NPN transistor and said second ESD current portion flows through said PNP transistor, and wherein said low voltage triggering device is in an off state during normal operation of said semiconductor device and wherein said low voltage triggering device is in an active state during said ESD event.
